(19) United States
(12) Patent Application Publication
(10) Pub. No.: US 2024/0332474 A1
(43) Pub. Date: Oct. 3, 2024

(54) ELECTRONIC DEVICE

(71) Applicant: CARUX TECHNOLOGY PTE. LTD., SINGAPORE (SG)

(72) Inventors: Chao-Sen Yang, Tainan (TW); Chao-Chin Sung, Tainan (TW); Chueh-Yuan Nien, Tainan (TW); Chien-Tzu Chu, Tainan (TW)

(73) Assignee: CARUX TECHNOLOGY PTE. LTD., SINGAPORE (SG)

(21) Appl. No.: 18/586,524

(22) Filed: Feb. 25, 2024

(30) Foreign Application Priority Data
Mar. 31, 2023 (CN) 202310338659.7

(51) Int. Cl. H01L 33/62; H01L 25/075; H01L 25/16; H01L 27/12

(52) U.S. Cl. CPC H01L 33/62; H01L 25/0753; H01L 25/167; H01L 27/124

(57) ABSTRACT

An electronic device is provided. The electronic device includes a substrate, a first conductive layer, an insulating layer, a second conductive layer, and an electronic element. The first conductive layer is disposed on the substrate and includes a first power line. The insulating layer is disposed on the first power line and has a first opening. The first opening exposes the first power line. The second conductive layer is disposed on the insulating layer. The second conductive layer includes a first conductive element. At least a portion of the first conductive element is disposed in the first opening and electrically connected to the first power line. The electronic element is disposed on the insulating layer and electrically connected to the first power line. The electronic device in the embodiments of the disclosure may reduce the resistivity of metal wires, improve the problem of IR drop, or uniform the emitted light.

### CROSS-REFERENCE TO RELATED APPLICATION

This application claims the priority benefit of China application serial no. 202310338659.7, filed on Mar. 31, 2023. The entirety of the above-mentioned patent application is hereby incorporated by reference herein and made a part of this specification.

### BACKGROUND

### Technical Field

The disclosure relates to an electronic device, in particular to an electronic device that may reduce the resistivity of metal wires, improve the problem of IR drop, or uniform the emitted light.

### Description of Related Art

Electronic devices or splicing electronic devices has been widely applied in different fields such as communication, display, vehicle, or aviation. With the vigorous development of electronic devices, the electronic devices are becoming thinner and lighter, which has led to higher requirements for the reliability or quality of the electronic devices.

### SUMMARY

The disclosure provides an electronic device that may reduce the resistivity of metal wires, improve the problem of IR drop, or uniform the emitted light.

According to an embodiment of the disclosure, the electronic device includes a substrate, a first conductive layer, an insulating layer, a second conductive layer, and an electronic element. The first conductive layer is disposed on the substrate and includes a first power line. The insulating layer is disposed on the first power line and has a first opening. The first opening exposes the first power line. The second conductive layer is disposed on the insulating layer. The second conductive layer includes a first conductive element. At least a portion of the first conductive element is disposed in the first opening and electrically connected to the first power line. The electronic element is disposed on the insulating layer and electrically connected to the first power line.

### BRIEF DESCRIPTION OF THE DRAWINGS

The accompanying drawings are included to provide a further understanding of the disclosure, and are incorporated in and constitute a part of this specification. The drawings illustrate embodiments of the disclosure, and together with the description serve to explain principles of the disclosure.

FIG. 1A is a partial top schematic view of an electronic device according to the first embodiment of the disclosure.

FIG. 1B is a cross-sectional schematic view of the electronic device of FIG. 1A along the profile line I-I′.

FIG. 1C is a cross-sectional schematic view of the electronic device of FIG. 1A along the profile line II-II′.

FIG. 1D is a cross-sectional schematic view of the electronic device of FIG. 1A along the profile line III-III′.

FIG. 2A is a partial top schematic view of an electronic device according to the second embodiment of the disclosure.

FIG. 2B is a cross-sectional schematic view of the electronic device of FIG. 2A along the profile line IV-IV′.

FIG. 3 is a partial top schematic view of an electronic device according to the third embodiment of the disclosure.

FIG. 4 is a partial top schematic view of an electronic device according to the fourth embodiment of the disclosure.

FIG. 5 is a partial top schematic view of an electronic device according to the fifth embodiment of the disclosure.

FIG. 6 is a cross-sectional schematic view of an electronic device according to the first embodiment of the disclosure.

### DESCRIPTION OF THE EMBODIMENTS

The disclosure can be understood by referring to the following detailed description in conjunction with the accompanying drawings. It should be noted that, for the ease of understanding by the readers and for the brevity of the accompanying drawings, multiple drawings in the disclosure only depict a portion of the electronic device, and the specific elements in the drawings are not drawn according to the actual scale. In addition, the number and size of each of the elements in the figures are for illustration purposes only, and are not intended to limit the scope of the disclosure.

In the following description and claims, words such as “comprising” and “including” are open-ended words, so they should be interpreted as meaning “including but not limited to . . . ”.

It should be understood that when an element or layer is referred to as being “on” or “connected to” another element or layer, it may be directly on or directly connected to this other element or layer, or there may be an intervening element or layer in between (indirect case). In contrast, when an element is referred to as being “directly on” or “directly connected to” another element or layer, there are no intervening elements or layers present.

Although the terms “first”, “second”, “third”, . . . may be used to describe various constituent elements, the constituent elements are not limited by the terms. The terms are only used to distinguish a single constituent element from other constituent elements in the specification. The same terms may not be used in the claim, but replaced by first, second, third . . . according to the order in which the elements are declared in the claim. Therefore, in the following description, the first constituent element may be the second constituent element in the claim.

As used herein, the terms “about,” “approximately,” “substantially,” and “roughly” generally mean within 10%, within 5%, within 3%, within 2%, within 1%, or within 0.5% of a given value or range. The quantity given here is an approximate quantity, that is, even though “about,” “approximately,” “substantially,” and “roughly” are not specified, the meaning of “about,” “approximately,” “substantially,” and “roughly” are still implied.

In some embodiments of the disclosure, terms related to joining and connecting, such as “connected”, “interconnected”, etc., unless otherwise defined, may mean that two structures are in direct contact, or may also mean that two structures are not in direct contact, in which there are other structures located between these two structures. The terms related to joining and connecting can also include the case where both structures are movable, or both structures are fixed. Furthermore, the term “coupled” includes any direct and indirect means of electrical connection.

In some embodiments of the disclosure, optical microscopy (OM), scanning electron microscope (SEM), film thickness profiler (α-step), ellipsometer, or other suitable methods may be used to measure the area, width, thickness, or height of each element, or the distance or pitch between elements. In detail, according to some embodiments, a scanning electron microscope can be used to obtain a cross-sectional structure image including a component to be measured, and to measure the area, width, thickness, or height of each element, or the distance or pitch between elements.

The electronic device of this disclosure may include a display apparatus, an antenna device, a sensing device, or a splicing device, but is not limited thereto. The electronic device may be a bendable or flexible electronic device. The electronic device may, for example, include a liquid crystal light-emitting diode; the light-emitting diode may include, for example, an organic light-emitting diode (OLED), a mini light-emitting diode (mini LED), a micro light-emitting diode (micro LED), or a quantum dot light-emitting diode (quantum dot, QD, such as QLED, QDLED), fluorescence, phosphor, or other suitable materials, and the materials can be any arrangement and combination, but not limited thereto. The antenna device may be, for example, a liquid crystal antenna, but not limited thereto. The splicing device may be, for example, a display splicing device or an antenna splicing device, but not limited thereto. It should be noted that, the electronic device can be any arrangement and combination of the foregoing, but not limited thereto. Hereinafter, an electronic device is used to illustrate the disclosure, but the disclosure is not limited thereto.

It should be noted that, in the following embodiments, the features in several different embodiments can be replaced, reorganized, and mixed to complete other embodiments without departing from the spirit of the disclosure. As long as the features of the various embodiments do not violate the spirit of the disclosure or conflict with one another, they can be mixed and matched arbitrarily.

References of the exemplary embodiments of the disclosure are to be made in detail. Examples of the exemplary embodiments are illustrated in the drawings. If applicable, the same reference numerals in the drawings and the descriptions indicate the same or similar parts.

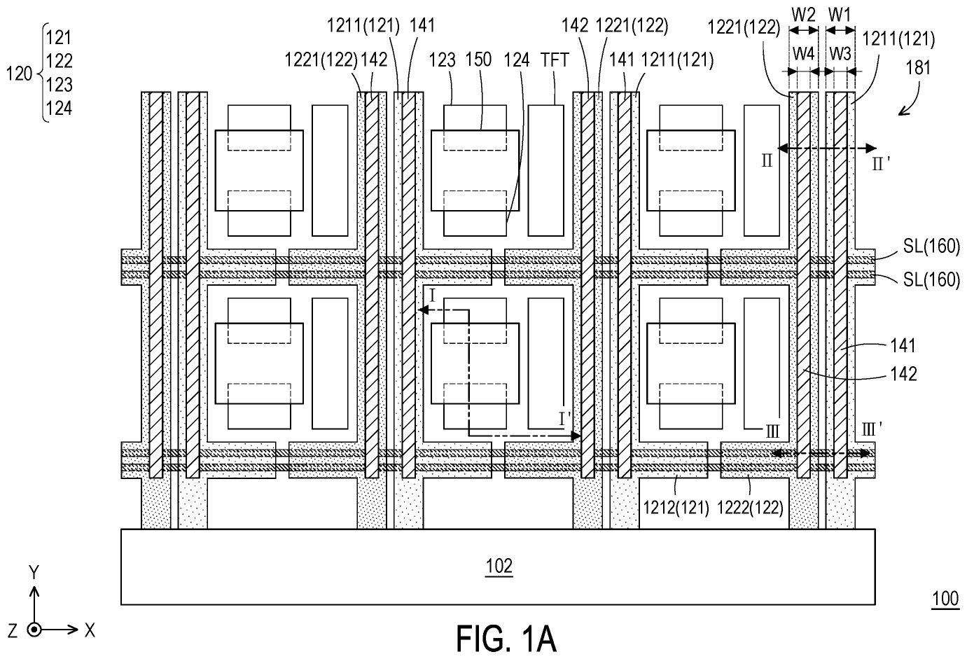

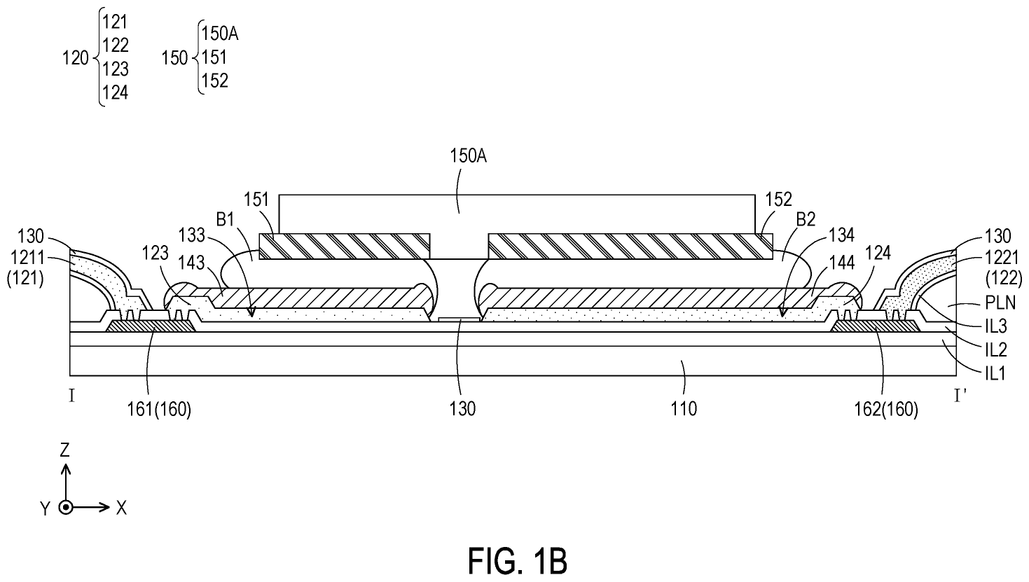

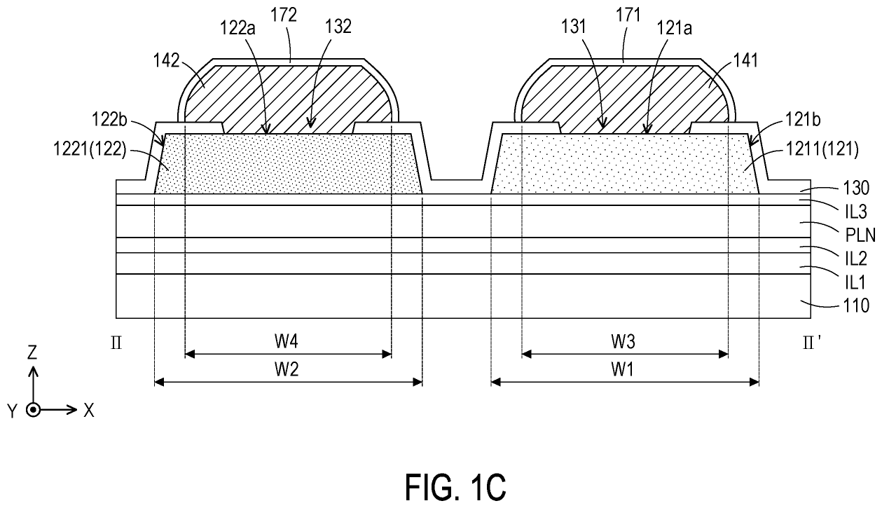

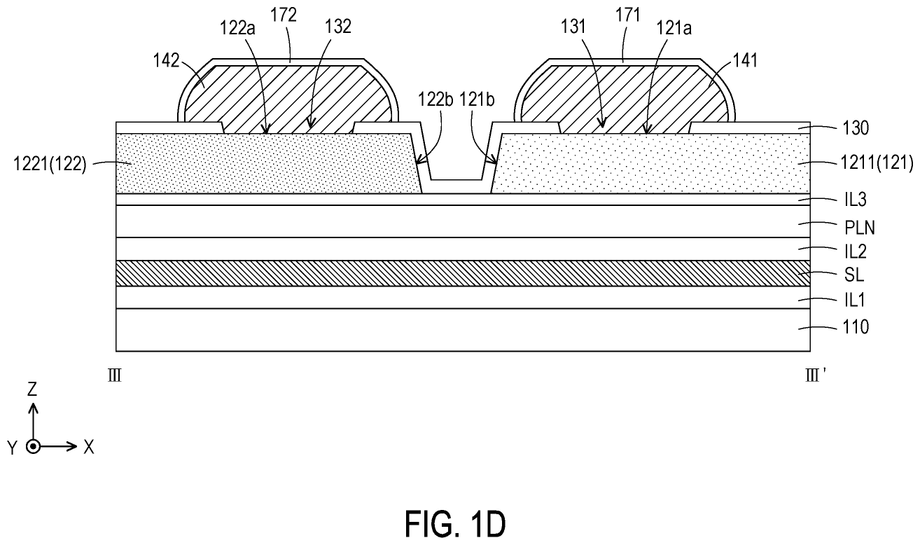

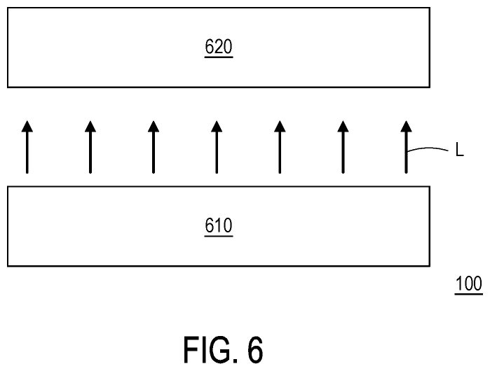

FIG. 1A is a partial top schematic view of an electronic device according to the first embodiment of the disclosure. FIG. 1B is a cross-sectional schematic view of the electronic device of FIG. 1A along the profile line I-I′. FIG. 1C is a cross-sectional schematic view of the electronic device of FIG. 1A along the profile line II-II′. FIG. 1D is a cross-sectional schematic view of the electronic device of FIG. 1A along the profile line III-III′. FIG. 6 is a cross-sectional schematic view of an electronic device according to the first embodiment of the disclosure. For clarity and convenience of illustration, several elements in an electronic device 100 are omitted in FIG. 1A.

Referring to FIG. 1A, the electronic device 100 includes an electronic element plate 181 and a driving element 102. The electronic element plate 181 includes multiple electronic elements 150. The electronic elements 150 are arranged in an array. The electronic element plate 181 may be a light board. The driving element 102 may be electrically connected to the electronic elements 150 to supply power to the electronic elements 150 in the electronic element plate 181. In this embodiment, the electronic element 150 may be, for example, a light-emitting unit, such as a pixel; and the driving element 102 may be, for example, a printed circuit board or a flexible printed circuit board (FPC), but is not limited thereto. For the convenience of illustration, six electronic elements 150 are shown in FIG. 1A, but the disclosure is not limited thereto. According to some embodiments, the electronic element plate 181 may include more than six electronic elements 150. That is, FIG. 1A shows a partial top view of the electronic device 100.

According to some embodiments, as shown in FIG. 6, the electronic device 100 may include a light source module 610 and a display panel 620. The light source module 610 may include an electronic element plate 181 and a driving element 102. The electronic element plate 181 may be a light board, and the electronic element 150 may be a light-emitting unit. The light source module 610 may provide a light source L to the display panel 620. The display panel 620 may be a liquid crystal display panel.

Referring to FIG. 1A to FIG. 1D at the same time, the electronic device 100 includes an electronic element plate 181. The electronic element plate 181 includes a substrate 110, a first conductive layer 120, an insulating layer 130, a second conductive layer 140, and an electronic element 150. The first conductive layer 120, the insulating layer 130, the second conductive layer 140, and the electronic element 150 may be arranged on the substrate 110 in sequence. Specifically, the first conductive layer 120 is disposed on the substrate 110, the insulating layer 130 is disposed on the first conductive layer 120, and the second conductive layer 140 is disposed on the insulating layer 130.

The electronic device 100 of this embodiment may include a substrate 110, a first conductive layer 120, an insulating layer 130, a second conductive layer 140, and an electronic element 150. The substrate 110 may include a rigid substrate, a flexible substrate or a combination thereof. For example, the material of the substrate 110 may include glass, quartz, sapphire, ceramic, polycarbonate (PC), polyimide (PI), polyethylene terephthalate (PET), other suitable substrate materials, or a combination thereof, but not limited thereto. The electronic element 150 may be, for example, a light-emitting diode. According to some embodiments, the light-emitting diode 150 may include a P-type semiconductor, an N-type semiconductor, and a light-emitting layer.

In this embodiment, as shown in FIG. 1B, the electronic device 100 may further include an insulating layer IL1, an insulating layer IL2, an insulating layer PLN, and an insulating layer IL3. The insulating layer IL1 is disposed on the substrate 110, the insulating layer IL2 is disposed on the insulating layer IL1, the insulating layer PLN is disposed on the insulating layer IL2, and the insulating layer IL3 is disposed on the insulating layer PLN. The insulating layer IL1, the insulating layer IL2, the insulating layer IL3, and the insulating layer PLN may be a monolayer structure or a multilayer structure. The materials of the insulating layer IL1, the insulating layer IL2, the insulating layer IL3, and the insulating layer PLN may include organic materials, inorganic materials (e.g., silicon nitride or silicon oxide), or a combination thereof, but not limited thereto.

As shown in FIG. 1C, the first conductive layer 120 is disposed on the substrate 110. The first conductive layer 120 may be patterned to form multiple power lines, that is, the first conductive layer 120 may include multiple power lines. According to some embodiments, the first conductive layer 120 may be disposed on the insulating layer IL3, and the first conductive layer 120 may include a first power line 121. The first power line 121 has an upper surface 121a, a lateral surface 121b, and a bottom surface. The upper surface 121a and the bottom surface are opposite to each other. The upper surface 121a is a surface of the first power line 121 away from the substrate 110, and the lateral surface 121b may connect the upper surface 121a and the bottom surface. The first power line 121 may be electrically connected to the driving element 102. For example, at least a portion of the first power line 121 (e.g., a main line 1211) may extend to the driving element 102 in a first direction Y and be electrically connected to the driving element 102. As shown in FIG. 1B, the first power line 121 may be electrically connected to the electronic element 150 through a first connecting portion 161. The electronic element 150 is disposed on the insulating layer 130 and is electrically connected to the first power line 121. The electronic elements 150 arranged in the first direction Y may be electrically connected to the same first power line 121 and the same second power line 122.

As shown in FIG. 1A, the first power line 121 includes a main line 1211 and a branch 1212, and the main line 1211 may be connected to the branch 1212. In the top view of the electronic device 100 (e.g., FIG. 1A), the main line 1211 may extend in the first direction Y and the branch 1212 may extend in the second direction X. The first direction Y and the second direction X are different, but not limited thereto. For example, the first direction and the second direction may be perpendicular. The main line 1211 has a width W1. The width W1 is, for example, a maximum width of the main line 1211 measured in the second direction X.

In this embodiment, as shown in FIG. 1A and FIG. 1C, the first conductive layer 120 further includes a second power line 122. The second power line 122 has an upper surface 122a and a lateral surface 122b. The upper surface 122a is a surface of the second power line 122 away from the substrate 110, and the lateral surface 122b may connect the upper surface 122a. The second power line 122 may be electrically connected to the driving element 102. For example, at least a portion of the second power line 122 (e.g., a main line 1221) may extend to the driving element 102 in a first direction Y and be electrically connected to the driving element 102. As shown in FIG. 1B, the second power line 122 may be electrically connected to the electronic element 150 through a second connecting portion 162. A connecting layer 160 may be disposed between the insulating layer IL2 and the insulating layer IL1. The connecting layer 160 may include a first connecting portion 161 and a second connecting portion 162. That is, the first connecting portion 161 and the second connecting portion 162 may be the same layer.

In this embodiment, the first power line 121 and the second power line 122 may transmit different power signals, respectively. For example, the first power line 121 may transmit a high power voltage (VDD), and the second power line 122 may transmit a low power voltage (VSS), but not limited thereto. Therefore, the driving element 102 may drive the electronic element 150 through the first power line 121 and the second power line 122. In this way, one electronic element 150 may be provided with the high power voltage (VDD) via the first power line 121 and the low power voltage (VSS) via the second power line 122.

In this embodiment, the second power line 122 includes a main line 1221 and a branch 1222, and the main line 1221 may be connected to the branch 1222. In the top view of the electronic device 100 (e.g., FIG. 1A), the main line 1221 may extend in the first direction Y and the branch 1222 may extend in the second direction X, but not limited thereto. The main line 1221 has a width W2. The width W2 is, for example, a maximum width of the main line 1221 measured in the second direction X.

In this embodiment, as shown in FIG. 1A and FIG. 1B, the electronic device 100 may include a first conductive pad 123 and a second conductive pad 124. In detail, the first conductive layer 120 further includes the first conductive pad 123 and the second conductive pad 124. That is, according to some embodiments, the first power line 121 and the first conductive pad 123 may be the same layer, and the second power line 122 and the second conductive pad 124 may be the same layer. The first conductive pad 123 and the second conductive pad 124 are disposed on the insulating layer IL2. In the cross-sectional view of the electronic device 100 (e.g., FIG. 1B), the first conductive pad 123 and the second conductive pad 124 may overlap with the electronic element 150 in a normal direction (i.e., direction Z) of the substrate 110. For example, in the normal direction of the substrate 110, at least a portion of the first conductive pad 123 may overlap with the electronic element 150, and at least a portion of the second conductive pad 124 may overlap with the electronic element 150. The first conductive pad 123 and the second conductive pad 124 may be electrically connected to the electronic element 150, respectively.

In this embodiment, the second direction X, the first direction Y, and the direction Z are different directions, respectively. The second direction X is, for example, an extending direction of the scan line SL, the first direction Y is, for example, an extending direction of the main line 1211 of the first power line 121 or the main line 1221 of the second power line 122, and the direction Z is, for example, the normal direction of the substrate 110. The second direction X is substantially perpendicular to the first direction Y, and the second direction X and the first direction Y are respectively substantially perpendicular to the direction Z, but not limited thereto.

As shown in FIG. 1C, the insulating layer 130 is disposed on the first power line 121 and the second power line 122, and the insulating layer 130 may cover a portion of the first power line 121 and a portion of the second power line 122. The insulating layer 130 may have a first opening 131, a second opening 132, a third opening 133 and, a fourth opening 134. The first opening 131 may expose at least a portion of the upper surface of the first power line 121, for example, exposing a portion of the upper surface 121a of the main line 1211 of the first power line 121. The insulating layer 130 may cover the lateral surface 121b of the first power line 121. The second opening 132 may expose at least a portion of the upper surface of the second power line 122, for example, exposing a portion of the upper surface 122a of the main line 1221 of the second power line 122. The insulating layer 130 may cover the lateral surface 122b of the second power line 122.

As shown in FIG. 1B, the third opening 133 may expose at least a portion of the upper surface of the first conductive pad 123, for example, exposing the entire upper surface of the first conductive pad 123. The fourth opening 134 may expose at least a portion of the upper surface of the second conductive pad 124, for example, exposing the entire upper surface of the second conductive pad 124. The insulating layer 130 may be regarded as a pixel definition layer (PDL), but not limited thereto.

According to some embodiments, as shown in FIG. 1B and FIG. 1C, the second conductive layer 140 may include a first conductive element 141, a second conductive element 142, a third conductive element 143, and a fourth conductive element 144. The first conductive element 141, the second conductive element 142, the third conductive element 143, and the fourth conductive element 144 are disposed on the insulating layer 130. At least a portion of the first conductive element 141 may further be disposed in the first opening 131, and the first conductive element 141 may be electrically connected to the first power line 121, for example, electrically connected to the main line 1211 of the first power line 121. At least a portion of the second conductive element 142 may further be disposed in the second opening 132, and the second conductive element 142 may be electrically connected to the second power line 122, for example, electrically connected to the main line 1221 of the second power line 122. At least a portion of the third conductive element 143 may further be disposed in the third opening 133, and the third conductive element 143 may be electrically connected to the first conductive pad 123. At least a portion of the fourth conductive element 144 may further be disposed in the fourth opening 134, and the fourth conductive element 144 may be electrically connected to the second conductive pad 124. In some embodiments, the first conductive element 141 may be in contact with the main line 1211 of the first power line 121, the second conductive element 142 may be in contact with the main line 1221 of the second power line 122, the third conductive element 143 may be in contact with the first conductive pad 123, and the fourth conductive element 144 may be in contact with the second conductive pad 124, but not limited thereto. In this embodiment, the material of the first conductive element 141, the second conductive element 142, the third conductive element 143 and the fourth conductive element 144 may include metal, for example, including nickel, gold, copper, chromium, silver, zinc, a combination thereof, or other suitable conductive materials, but not limited thereto. According to some embodiments, the material of the first conductive element 141, the second conductive element 142, the third conductive element 143, and the fourth conductive element 144 may be nickel, for example.

As shown in FIG. 1B, the electronic element 150 includes a main body 150A, a first pad 151, and a second pad 152. The first pad 151 and the second pad 152 may be disposed on the main body 150A. For example, the first pad 151 and the second pad 152 may be disposed on a lower surface of the main body 150A. The lower surface is a surface facing the substrate 110, but the disclosure is not limited thereto. The electronic element 150 may be bonded to the first conductive pad 123. In detail, the first power line 121 may be connected to the first conductive pad 123 via the first connecting portion 161. The insulating layer 130 has a third opening 133, and the third opening 133 exposes the first conductive pad 123. At least a portion of the third conductive element 143 is disposed in the third opening 133 and electrically connected to the first conductive pad 123. The third conductive element 143 may be connected to the first pad 151 of the electronic element 150 via a bonding element B1. In this way, the electronic element 150 may be bonded to the first conductive pad 123 via the bonding element B1 and the third conductive element 143. In this way, the first power line 121 may be electrically connected to the electronic element 150 and may provide power to the electronic element 150.

Similarly, as shown in FIG. 1B, the second power line 122 may be connected to the second conductive pad 124 via the second connecting portion 162. The insulating layer 130 has a fourth opening 134, and the fourth opening 134 exposes the second conductive pad 124. At least a portion of the fourth conductive element 144 is disposed in the fourth opening 134 and electrically connected to the second conductive pad 124. The fourth conductive element 144 may be connected to the second pad 152 of the electronic element 150 via a bonding element B2. In this way, the electronic element 150 may be bonded to the second conductive pad 124 via the bonding element B2 and the fourth conductive element 144. In this way, the second power line 122 may be electrically connected to the electronic element 150 and may provide power to the electronic element 150.

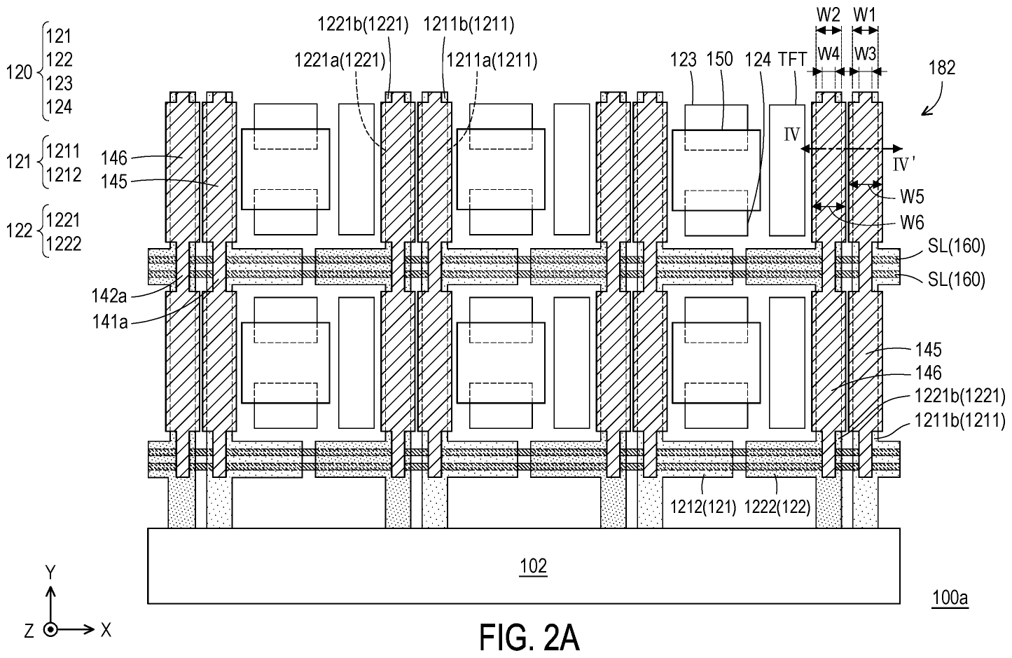

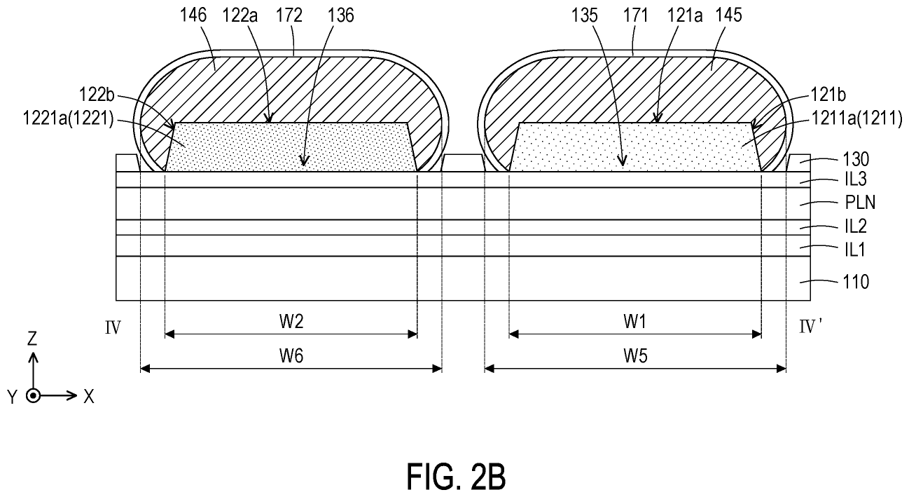

In this embodiment, the first conductive element 141 has a width W3, and the second conductive element 142 has a width W4. The width W3 is, for example, a maximum width of the first conductive element 141 measured in the second direction X. The width W4 is, for example, a maximum width of the second conductive element 142 measured in the second direction X. In this embodiment, the width W3 of the first conductive element 141 may be less than the width W1 of the main line 1211 of the first power line 121, and the width W4 of the second conductive element 142 may be less than the width W2 of the main line 1221 of the second power line 122, but not limited to this. In some embodiments, the width of the first conductive element may also be greater than the width of the main line of the first power line or the width of the main line of the second power line, as shown in FIG. 2A and FIG. 2B.

According to some embodiments, as shown in FIG. 1A and FIG. 1C, in the normal direction (i.e., direction Z) of the substrate 110, the first conductive element 141 may overlap with the first power line 121. For example, the first conductive element 141 may overlap with at least a portion of the first power line 121. For example, the first conductive element 141 may overlap with the main line 1211 of the first power line 121. In the normal direction of the substrate 110, the second conductive element 142 may overlap with the second power line 122. For example, the second conductive element 142 may overlap with at least a portion of the second power line 122. For example, the second conductive element 142 may overlap with the main line 1221 of the second power line 122.

According to some embodiments, as shown in FIG. 1B, the third conductive element 143 may overlap with and correspond to the first conductive pad 123 in the normal direction of the substrate 110, and the fourth conductive element 144 may overlap with and correspond to the second conductive pad 124 in the normal direction of the substrate 110. At least a portion of the first conductive element 141 may extend in the first direction Y, and at least a portion of the second conductive element 142 may extend in the first direction Y. For example, in the top view of the electronic device 100 (e.g., FIG. 1A), the first conductive element 141 and the second conductive element 142 may extend in the first direction Y, the first conductive element 141 extends in the same direction as the main line 1211 of the first power line 121, and the second conductive element 142 extends in the same direction as the main line 1221 of the second power line 122, but is not limited thereto.

As shown in FIG. 1A, the main line 1211 and the first conductive element 141 of the first power line 121 may extend in the first direction Y, and the main line 1221 and the second conductive element 142 of the second power line 122 may extend in the first direction Y. As shown in FIG. 1C, the first conductive element 141 is disposed in the first opening 131, and the second conductive element 142 is disposed in the second opening 132. For convenience of illustration, although the first opening 131 and the second opening 132 are not shown in FIG. 1A, according to some embodiments, the first opening 131 may extend in the first direction Y, and the second opening 132 may extend in the first direction Y. According to some embodiments that are not shown, in the first direction Y, the length of the first opening 131 may be different from (e.g., less than or greater than) the length of the main line 1211 of the first power line 121, and the length of the first conductive element 141 may be different from (e.g., less than or greater than) the length of the main line 1211 of the first power line 121. According to some embodiments that are not shown, in the first direction Y, the length of the first opening 131 may be different from (e.g., less than or greater than) the length of the first conductive element 141. For example, in the first direction Y, the main line 1211 of the first power line 121 may, for example, correspond to multiple first openings 131 (or multiple first conductive elements 141), and the first openings 131 (or the first conductive elements 141) are separated from each other. In the first direction Y, the first conductive element 141 may, for example, correspond to the first openings 131, and the first openings 131 are separated from each other. The term “correspond” in this disclosure may denote that two elements overlap with each other in a thickness direction (i.e., direction Z) of the substrate 110. For example, the first conductive element 141 corresponding to the first openings 131 may denote that the first conductive element 141 overlaps with the first openings 131 in the thickness direction (i.e., direction Z) of the substrate 110.

Similarly, according to some embodiments that are not shown, in the first direction Y, the length of the second opening 132 may be different from (e.g., less than or greater than) the length of the main line 1221 of the second power line 122, and the length of the second conductive element 142 may be different from (e.g., less than or greater than) the length of the main line 1221 of the second power line 122. According to some embodiments that are not shown, in the first direction Y, the length of the second opening 132 may be different from (e.g., less than or greater than) the length of the second conductive element 142. For example, in the first direction Y, the main line 1221 of the second power line 122 may, for example, correspond to multiple second openings 132 (or multiple second conductive elements 142), and the second openings 132 (or the second conductive elements 142) are separated from each other. In the first direction Y, the second conductive element 142 may, for example, correspond to the second openings 132, and the second openings 132 are separated from each other. According to some embodiments that are not shown, in the first direction Y, the length of the first opening 131 (or the length of the first conductive element 141) may be the same as the length of the main line 1211 of the first power line 121, and the length of the second opening 132 (or the length of the second conductive element 142) may be the same as the length of the main line 1221 of the second power line 122. According to some embodiments, the length of the first opening 131 may be the same as the length of the first conductive element 141, and the length of the second opening 132 may be the same as the length of the second conductive element 142.

As shown in FIG. 1C, in this embodiment, the electronic device 100 may further include third conductive layers 171 and 172. The third conductive layer 171 may be disposed on the first conductive element 141, and the third conductive layer 171 may cover the upper surface and the lateral surface of the first conductive element 141. Similarly, the third conductive layer 172 may be disposed on the second conductive element 142, and the third conductive layer 172 may cover the upper surface and the lateral surface of the second conductive element 142. In this embodiment, the material of the third conductive layers 171 and 172 may include metal, for example, including nickel, gold, copper, chromium, silver, zinc, a combination thereof, or other suitable conductive materials, but not limited thereto. According to some embodiments, the material of the third conductive layers 171 and 172 may be, for example, gold. According to some embodiments, the third conductive layer 171 may be electrically connected to the first conductive element 141, and the third conductive layer 172 may be electrically connected to the first conductive element 142.

In addition, as shown in FIG. 1B, in this embodiment, in the thickness direction (i.e., direction Z) of the substrate 110, the first power line 121 and the electronic element 150 may be disposed in a staggered manner. That is, in the thickness direction of the substrate 110, the first power line 121 does not overlap with the electronic element 150. Similarly, in the thickness direction of the substrate 110, the second power line 122 and the electronic element 150 may be disposed in a staggered manner, and the second power line 122 does not overlap with the electronic element 150.

In this embodiment, as shown in FIG. 1A, the electronic device 100 further includes a transistor TFT. The transistor TFT is disposed on the substrate 110. For convenience of illustration, the TFT in FIG. 1A are shown as squares. Although not shown in the figure, the TFT may be electrically connected to the electronic element 150 to drive the electronic element 150. According to some embodiments that are not shown, the transistor TFT may include an electrode, and the electrode may be, for example, a gate, a source, or a drain. According to some embodiments that are not shown, the electrode of the transistor TFT may be, for example, the same layer as the first conductive layer 120, but it is not limited thereto. That is, the first conductive layer 120 may include the electrode in the transistor TFT. Multiple scan lines SL are shown in FIG. 1A, which may extend in the second direction X, but is not limited thereto. Although not shown in the figure, the scan lines SL may be electrically connected to the corresponding transistors TFT to drive the electronic element 150 correspondingly electrically connected. The material of scan line SL may include molybdenum/aluminum/molybdenum alloy (Mo/Al/Mo alloy), titanium/aluminum/titanium alloy (Ti/Al/Ti alloy), suitable metal materials, or a combination thereof, but not limited thereto. Although not shown in the figure, the electronic element plate 181 may include multiple data lines, which are respectively electrically connected to the corresponding transistors TFT to drive the electronic element 150 corresponding electrically connected. The data lines may extend in the first direction Y. According to some embodiments, the first connecting portion 161 and the second connecting portion 162 in FIG. 1B may be at the same layer as the scan line SL. According to some embodiments, the first connecting portion 161 and the second connecting portion 162 in FIG. 1B may be at the same layer as the data line.

In the electronic device 100 of this embodiment, by disposing the first conductive element 141 on the main line 1211 of the first power line 121 and in the first opening 131 of the insulating layer 130 and electrically connecting the first conductive element 141 to the first power line 121, the first power line 121 and the first conductive element 141 may be connected in parallel to increase the metal area for transmitting power signal, thereby reducing the resistivity of metal wires, improving the problem of IR drop, or uniforming the light emitted by the electronic element 150 (e.g., light-emitting diode) in the electronic device 100. Similarly, by disposing the second conductive element 142 on the main line 1221 of the second power line 122 and in the second opening 132 of the insulating layer 130 and electrically connecting the second conductive element 142 to the second power line 122, the second power line 122 and the second conductive element 142 may be connected in parallel to increase the metal area for transmitting power signal, thereby reducing the resistivity of metal wires, improving the problem of IR drop, or uniforming the light emitted by the electronic element 150 (e.g., light-emitting diode) in the electronic device 100.

Other embodiments are described below for illustrative purposes. It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

FIG. 2A is a partial top schematic view of an electronic device according to the second embodiment of the disclosure. FIG. 2B is a cross-sectional schematic view of the electronic device of FIG. 2A along the profile line IV-IV′. Referring to FIG. 1A, FIG. 1C, FIG. 2A, and FIG. 2B at the same time, the electronic device 100a of this embodiment is similar to the electronic device 100 in FIG. 1A and FIG. 1C, but the main differences between the two is that a first conductive element 145 and a second conductive element 146 in an electronic element plate 182 in the electronic device 100a of this embodiment are designed differently from the first conductive element 141 and the second conductive element 142 in FIG. 1A.

Specifically, referring to FIG. 2A and FIG. 2B at the same time, in this embodiment, the main line 1211 of the first power line 121 may be divided into a first portion 1211a and a second portion 1211b, and the main line 1221 of the second power line 122 may be divided into a first portion 1221a and a second portion 1221b. The second portion 1211b of the main line 1211 of the first power line 121 may be connected to the first portion 1211a and the branch 1212, and the second portion 1221b of the main line 1221 of the second power line 122 may be connected to the first portion 1221a and the branch 1222. In some embodiments, the first portion 1211a of the first power line 121 (or the first portion 1221a of the second power line 122) does not overlap with and correspond to the scan line SL, and the second portion 1211b of the first power line 121 (or the second portion 1221b of the second power line 122) may partially overlap with and correspond to the scan line SL, but is not limited thereto.

The first opening (not shown) and the second opening (not shown) of the insulating layer 130 may be disposed corresponding to the second portion 1211b of the first power line 121 and the second portion 1221b of the second power line 122, respectively. The first conductive element 141a is disposed on the second portion 1211b of the first power line 121 and in the first opening of the insulating layer 130, and the second conductive element 142a is disposed on the second portion 1221b of the second power line 122 and in the second opening of the insulating layer 130.

The insulating layer 130 further includes a fifth opening 135 and a sixth opening 136. The fifth opening 135 and the sixth opening 136 may correspond to the first portion 1211a of the first power line 121 and the first portion 1221a of the second power line 122, respectively. The fifth opening 135 may expose the upper surface 121a and the lateral surface 121b of the first portion 1211a of the first power line 121, and the sixth opening 136 may expose the upper surface 122a and the lateral surface 122b of the first portion 1221a of the second power line 122.

The first conductive element 145 is disposed on the first portion 1211a of the first power line 121 and in the fifth opening 135 of the insulating layer 130, and the second conductive element 146 is disposed on the first portion 1221a of the second power line 122 and in the sixth opening 136 of the insulating layer 130. The first conductive element 145 may cover the upper surface 121a and the lateral surface 121b of the first portion 1211a of the first power line 121, and the second conductive element 146 may cover the upper surface 122a and the lateral surface 122b of the first portion 1221a of the second power line 122.

In this embodiment, the first conductive element 145 has a width W5, and second conductive element 146 has a width W6. The width W5 is, for example, a maximum width of the first conductive element 145 measured in the second direction X, and the width W6 is, for example, a maximum width of the second conductive element 146 measured in the second direction X. In this embodiment, the width W5 of the first conductive element 145 may be greater than the width W1 of the main line 1211 of the first power line 121, and the width W6 of the second conductive element 146 may be greater than the width W2 of the main line 1221 of the second power line 122, but not limited thereto.

In other words, the first conductive element (or the second conductive element) of this embodiment may have different widths due to being disposed at different positions on the main line 1211 (or the main line 1221). The width W5 of the first conductive element 145 corresponding to the first portion 1211a of the main line 1211 may be greater than the width W1 of the main line 1211, and the width W3 of the first conductive element 141a corresponding to the second portion 1211b may be less than the width W1 of the main line 1211. Similarly, the width W6 of the second conductive element 146 corresponding to the first portion 1221a of the main line 1221 may be greater than the width W2 of the main line 1221, and the width W4 of the second conductive element 142a corresponding to the second portion 1221b may be less than the width W2 of the main line 1221.

In the electronic device 100a of this embodiment, since the width W5 of the first conductive element 145 may be greater than the width W1 of the main line 1211 of the first power line 121, a metal area of the first power line 121 and the first conductive element 145 is further increased after parallel connection, thereby further reducing the resistivity of metal wires. Similarly, since the width W6 of the second conductive element 146 may be greater than the width W2 of the main line 1221 of the second power line 122, the metal area of the second power line 122 and the second conductive element 146 is further increased after parallel connection, thereby further reducing the resistivity of metal wires.

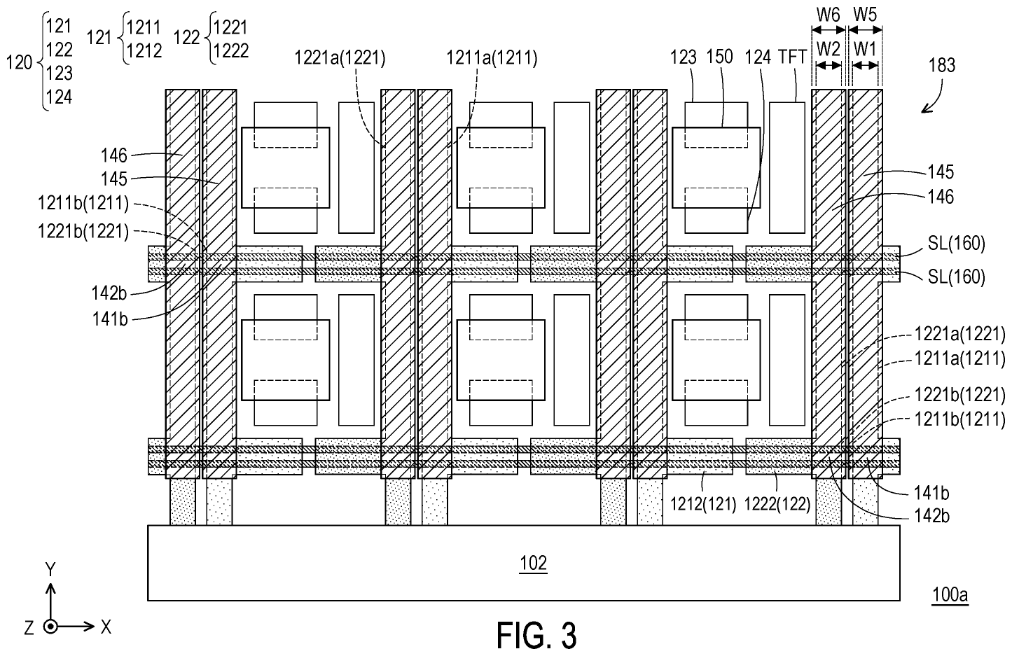

FIG. 3 is a partial top schematic view of an electronic device according to the third embodiment of the disclosure. Referring to FIG. 1 and FIG. 3 at the same time, the electronic device 100b of this embodiment is similar to the electronic device 100 in FIG. 1, but the main differences between the two is that in the electronic element plate 183 of the electronic device 100b of this embodiment, the first opening 131b and the second opening 132b of the insulating layer 130 may be disposed corresponding to the second portion 1211b of the first power line 121 and the second portion 1221b of the second power line 122, respectively. The first opening 131b of the insulating layer 130 may expose the upper surface 121a and the lateral surface 121b of the main line 1211 of the first power line 121, and the second opening 132b of the insulating layer 130 may expose the upper surface 122a and the lateral surface 122b of the main line 1221 of the second power line 122.

Specifically, referring to FIG. 3, in this embodiment, a first conductive element 141b is disposed on the second portion 1211b of the first power line 121 and in the first opening 131b of the insulating layer 130, and a second conductive element 142b is disposed on the second portion 1221b of the second power line 122 and in the second opening 132b of the insulating layer 130. The first conductive element 141b may cover the upper surface 121a and the lateral surface 121b of the second portion 1211b of the first power line 121, and the second conductive element 142b may cover the upper surface 122a and the lateral surface 122b of the second portion 1221b of the second power line 122.

In this embodiment, the first conductive element 141b has a width W5, and the second conductive element 142b has a width W6. The width W5 is, for example, a maximum width of the first conductive element 141b measured in the second direction X, and the width W6 is, for example, a maximum width of the second conductive element 142b measured in the second direction X. In this embodiment, the width W5 of the first conductive element 141b may be greater than the width W1 of the main line 1211 of the first power line 121, and the width W6 of the second conductive element 142b may be greater than the width W2 of the main line 1221 of the second power line 122, but not limited thereto.

In other words, the first conductive element of this embodiment has the same width whether it is disposed on the first portion 1211a or the second portion 1211b of the main line 1211, and the second conductive element of this embodiment also has the same width whether it is disposed on the first portion 1221a or the second portion 1221b of the main line 1221. The width W5 of the first conductive element 145 corresponding to the first portion 1211a of the main line 1211 may be substantially equal to the width W5 of the first conductive element 141b corresponding to the second portion 1211b. Similarly, the width W6 of the second conductive element 146 corresponding to the first portion 1221a of the main line 1221 may also be substantially equal to the width W6 of the second conductive element 142b corresponding to the second portion 1221b.

In the electronic device 100b of this embodiment, since the width W5 of the first conductive element 141b may be greater than the width W1 of the main line 1211 of the first power line 121, a metal area of the first power line 121 and the first conductive element 141b is further increased after parallel connection, thereby further reducing the resistivity of metal wires. Similarly, since the width W6 of the second conductive element 142b may be greater than the width W2 of the main line 1221 of the second power line 122, the metal area of the second power line 122 and the second conductive element 142b is further increased after parallel connection, thereby further reducing the resistivity of metal wires.

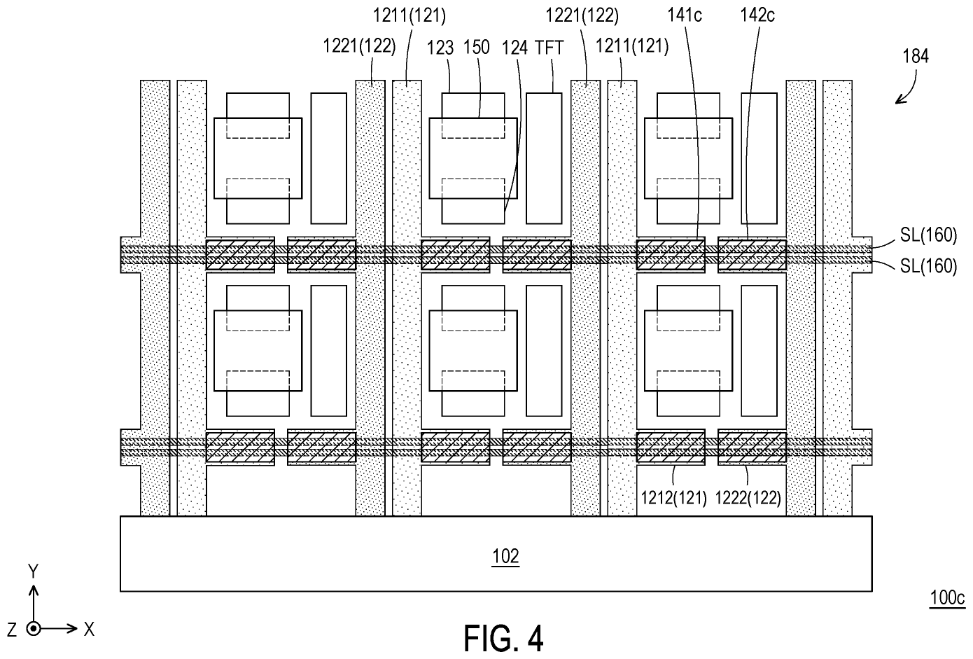

FIG. 4 is a partial top schematic view of an electronic device according to the fourth embodiment of the disclosure. Referring to FIG. 1A and FIG. 4 at the same time, the electronic device 100c of this embodiment is similar to the electronic device 100 in FIG. 1A, but the main differences between the two is that in the electronic element plate 184 of the electronic device 100c of this embodiment, a first conductive element 141c is disposed corresponding to the branch 1212 of the first power line 121, and a second conductive element 142c is disposed corresponding to the branch 1222 of the second power line 122.

Specifically, referring to FIG. 4, different from the electronic device 100 in FIG. 1A, the electronic device 100c of this embodiment does not have the first conductive element disposed on the main line 1211 of the first power line 121 and the main line 1221 of the second power line 122. However, the electronic device 100c of this embodiment may have the first conductive element 141c and the second conductive element 142c disposed on the branch 1212 of the first power line 121 and the branch 1222 of the second power line 122, respectively. The first conductive element 141c may overlap with and corresponds to the branch 1212 of the first power line 121 in the normal direction (i.e., direction Z) of the substrate 110, and the second conductive element 142c may overlap with and corresponds to the branch 1222 of the second power line 122 in the normal direction of the substrate 110. In some embodiments, the first conductive element 141c may be in contact with the branch 1212 of the first power line 121, and the second conductive element 142c may be in contact with the branch 1222 of the second power line 122, but not limited thereto. At least a portion of the first conductive element 141c may extend in the second direction X, and at least a portion of the second conductive element 142c may extend in the second direction X For example, the first conductive element 141c may extend in the second direction X, and the second conductive element 142c may also extend in the second direction X.

As shown in FIG. 4, the branch 1212 and the first conductive element 141c of the first power line 121 may extend in the second direction X, and the branch 1222 and the second conductive element 142c of the second power line 122 may extend in the second direction X. Similar to FIG. 1C, the first conductive element 141c is disposed in the first opening 131, and the second conductive element 142c is disposed in the second opening 132. According to some embodiments, in the embodiment shown in FIG. 4, the first opening 131 may extend in the second direction X, and the second opening 132 may extend in the second direction X. According to some embodiments, in the second direction X, the length of the first opening 131 may be different from (e.g., less than or greater than) the length of the branch 1212 of the first power line 121, and the length of the first conductive element 141c may be different from (e.g., less than or greater than) the length of the branch 1212 of the first power line 121. According to some embodiments, in the second direction X, the length of the first opening 131 may be different from (e.g., less than or greater than) the length of the first conductive element 141c, and the length of the second opening 132 may be different from (e.g., less than or greater than) the length of the second conductive element The length of 142c. For example, in the second direction X, the branch 1212 of the first power line 121 may, for example, correspond to multiple first openings 131 (or multiple first conductive elements 141c), and the first openings 131 (or the first conductive elements 141c) are separated from each other. Similarly, in the second direction X, the length of the second opening 132 may be different from (e.g., less than or greater than) the length of the branch 1222 of the second power line 122, and the length of the second conductive element 142c may be different from (e.g., less than or greater than) the length of the branch 1222 of the second power line 122. For example, in the second direction X, the branch 1222 of the second power line 122 may, for example, correspond to multiple second openings 132 (or multiple second conductive elements 142c), and the second openings 132 (or the second conductive elements 142c) are separated from each other. In the second direction X, the first conductive element 141c may, for example, correspond to the first openings 131, and the first openings 131 are separated from each other. In the second direction X, the second conductive element 142c may, for example, correspond to the second openings 132, and the second openings 132 are separated from each other. According to some embodiments, in the second direction X, the length of the first opening 131 (or the length of the first conductive element 141c) may be the same as the length of the branch 1212 of the first power line 121, and the length of the second opening 132 (or the length of the second conductive element 142c) may be the same as the length of the branch 1222 of the second power line 122. According to some embodiments, in the second direction X, the length of the first opening 131 may be the same as the length of the first conductive element 141c, and the length of the second opening 132 may be the same as the length of the second conductive element 142c.

In the electronic device 100c of this embodiment, by disposing the first conductive element 141c on the branch 1212 of the first power line 121 and electrically connecting the first conductive element 141c to the first power line 121, the first power line 121 and the first conductive element 141c may be connected in parallel to increase the metal area for transmitting power signal, thereby reducing the resistivity of metal wires, improving the problem of IR drop, or uniforming the light emitted by the electronic element 150 (e.g., light-emitting diode) in the electronic device 100c. Similarly, by disposing the second conductive element 142c on the branch 1222 of the second power line 122 and electrically connecting the second conductive element 142c to the second power line 122, the second power line 122 and the second conductive element 142c may also be connected in parallel to increase the metal area for transmitting power signal, thereby reducing the resistivity of metal wires, improving the problem of IR drop, or uniforming the light emitted by the electronic element 150 (e.g., light-emitting diode) in the electronic device 100c.

According to some embodiments, although it is not shown in the figure, the design of the conductive element above the power line may combine the designs of FIG. 1A and FIG. 4. That is, in the combined design of FIG. 1A and FIG. 4, similar to the design of the first power line, the first conductive element above the first power line may also include the main line and the branch. Specifically, the main line of the first conductive element (namely, the first portion) is disposed above the main line 1211 of the first power line 121 and may have the same extension direction as the main line 1211 of the first power line 121, that is, extending in the first direction Y as the first conductive element 141 in FIG. 1A. The branch of the first conductive element (namely, the second portion) is disposed above the branch 1212 of the first power line 121 and may have the same extension direction as the branch 1212 of the first power line 121, that is, extending in the second direction X, as the first conductive element 141c in FIG. 4. That is, the first conductive element may include a first portion extending in a first direction and a second portion extending in a second direction. Similar to FIG. 1C, the first conductive element may be disposed in the opening 131 and electrically connected to the first power line 121. According to some embodiments, the opening 131 may also include two portions. The first portion of the first conductive element may be disposed in the first portion of the opening, and the second portion of the first conductive element may be disposed in the second portion of the opening. The first portion and the second portion of the opening may be separated. Alternatively, the first portion and the second portion of the opening may be connected.

In the combined design of FIG. 1A and FIG. 4, the second conductive element above the second power line may also have a similar design to the first conductive element mentioned in the preceding paragraphs, and details will not be repeated herein. The opening connecting the second conductive element and the second power line may also have a similar design to the opening mentioned in the preceding paragraphs, and details will not be repeated herein.

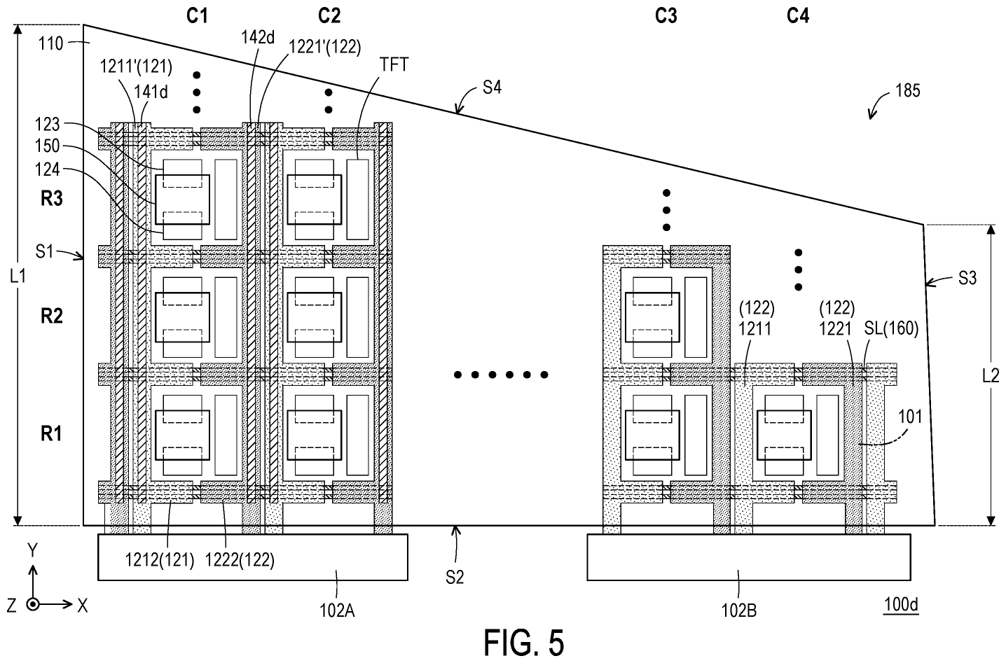

FIG. 5 is a partial top schematic view of an electronic device according to the fifth embodiment of the disclosure. Referring to FIG. 1A and FIG. 5 at the same time, the electronic device 100d of this embodiment is similar to the electronic device 100 in FIG. 1A, but the main differences between the two is that in the electronic element plate 185 of the electronic device 100d of this embodiment, a profile shape of the substrate 110 is an irregular shape, a first conductive element 141d is not provided on all the first power lines 121, and the second conductive element 142d is not provided on all second power lines 122. In addition, in FIG. 5, the electronic device 100d includes an electronic element plate 185 (e.g., a light board) and two driving elements 102A and 102B. The two driving elements 102A and 102B are respectively electrically connected to the electronic elements 150 in different regions on different electronic element plates 185. FIG. 5 illustrates an example with two driving elements. According to other embodiments, the electronic device may include more than two driving elements to be electrically connected to the light-emitting unit on the light board. According to some embodiments, the electronic device may include an electronic element plate and multiple driving elements, the driving elements are respectively configured to drive different regions of the electronic element plate, and the number of the driving elements may be two or more. For example, as shown in FIG. 5, the driving element 102A may be configured to electrically connect with the electronic element 150 in regions C1 and C2 of the electronic element plate and drive the electronic element 150 in the regions C1 and C2. The driving element 102B may be configured to electrically connect with the electronic element 150 in regions C3 and C4 of the electronic element plate and drive the electronic element 150 in the regions C3 and C4.

Specifically, referring to FIG. 5, in this embodiment, the profile shape of the substrate 110 may be, for example, an irregular quadrilateral, but is not limited thereto. Specifically, the four lateral sides of the substrate 110 are lateral side S1, lateral side S2, lateral side S3, and lateral side S4. The lateral side S1 and the lateral side S3 are opposite to each other, and the lateral side S2 and the lateral side S4 are opposite to each other. The lateral side S2 is connected to the lateral side S1 and the lateral side S3, and the lateral side S4 is connected to the lateral side S1 and the lateral side S3. The lateral side S1 and the lateral side S3 may generally extend in the first direction Y, and the lateral side S2 may generally extend in the second direction X. The lateral side S2 and the lateral side S4 may not be parallel. In addition, in the first direction Y, the length L1 of the lateral side S1 and the length L2 of the lateral side S3 may be unequal. For example, the length L1 of the lateral side S1 may be greater than the length L2 of the lateral side S3.

In this embodiment, multiple electronic elements 150 are arranged on the substrate 110 in an array arrangement. In the second direction X, the electronic elements 150 are schematically divided into four columns, namely column C1, column C2, column C3, and column C4, but not limited thereto; and in the first direction Y, the electronic elements 150 are schematically divided into three rows, namely, row R1, row R2, and row R3, but not limited thereto. In some embodiments, there may be more columns and electronic elements arranged in array between column C2 and column C3. In some embodiments, there may be more rows and more electronic elements after row R3 in column C1 and column C2 (or after row R2 in column C3, or after row R1 in column C4). The number of columns and rows on the electronic element plate 185 are for example only, and are not used to limit the disclosure.

In this embodiment, column C1 is closer to the lateral side S1 than column C4, and row R1 is closer to the lateral side S2 than row R3. In this embodiment, since the length of the lateral side S1 may be greater than the length of the lateral side S3 in the first direction Y, more electronic elements 150 may be disposed on a region on the substrate 110 adjacent to the lateral side S1 (e.g., column C1) compared to a region on the substrate 110 adjacent to the lateral side S3 (e.g., column C4). For example, three electronic elements 150 are schematically disposed in column C1, and one electronic element 150 is schematically disposed in column C4.

Continuing with reference to FIG. 5, in the first direction Y, since the length L1 of the lateral side S1 may be greater than the length L2 of the lateral side S3 in the first direction Y, the distance between the electronic element 150 located in column C1 and row R3 (or the electronic element 150 farthest from the driving element 102A in column C1) and the driving element 102A is significantly greater than the distance between the electronic element 150 located in column C4 and row R1 (or the electronic element 150 farthest from the driving element 102B in column C4) and the driving element 102B (i.e., the electronic element 150 on row R3 is significantly farther from the driving element 102A or the driving element 102B than the electronic element 150 in row R1). Thus, the voltage received by the electronic element 150 located in column C1 and row R3 is significantly lower than the voltage received by the electronic element 150 located in column C4 and row R1, which leads to the problem of IR drop in the electronic element 150 located in column C1 and row R3, but the electronic element 150 located in column C4 and row R1 is less likely to have the problem of IR drop. According to some embodiment, since length L1 is greater than L2, in the first direction Y, the distance between the electronic element 150 (although not shown) farthest from the driving element 102A in column C1 and the driving element 102A is significantly greater than the distance between the electronic element 150 furthest from the driving element 102B in column C4 and the driving element 102B (although not shown). In the first direction Y, compared with the farthest electronic element in column C4, the farthest electronic element in column C1 is more likely to have the problem of IR drop.

As mentioned above, in FIG. 5, since L1 is greater than L2, for the electronic element in column C1, there is a problem of IR drop. Thus, in this embodiment, a first conductive element 141d is provided on the main line 1211′ of the first power line 121 electrically connecting the driving element 102A and the electronic elements 150 in column C1, and a second conductive element 142d is provided on the main line 1221′ of the second power line 122 electrically connecting the driving element 102A and the electronic elements 150 in column C1. In this way, the main line 1211′ of the first power line 121 and the first conductive element 141d may be connected in parallel, and/or the main line 1221′ of the second power line 122 may be connected in parallel with the second conductive element 142d. In this way, the conductive area for transmitting power signal may be increased, thereby reducing the resistivity of wires, improving the problem of IR drop, or uniforming the light emitted by the electronic element 150 (e.g., light-emitting diode) in the electronic device 100d. In addition, since L2 is smaller than L1, in the first direction Y, among the electronic elements in C4, the voltages received by the electronic elements farther and closer to the driving element 102B do not have a great difference. That is, the electronic element 150 in C4 is not likely to have a problem of IR drop. Therefore, in this embodiment, no first conductive element 141d is required to be additionally provided on the main line 1211 of the first power line 121 electrically connecting the driving element 102B and the electronic elements 150 located in column C4, and no additional second conductive element 142d is required to be additionally provided on the main line 1221 of the second power line 122 electrically connecting the driving element 102B and the electronic element 150 of C4. Similarly, no first conductive element 141d (or second conductive element 142d) is required to be additionally provided on the main line 1211 of the first power line 121 (or on the main line 1221 of the second power line 122) electrically connecting the driving element 102B and the electronic elements 150 in column C3.

Although this embodiment schematically shows 9 electronic elements 150, and the 9 electronic elements 150 are schematically arranged in 4 columns and 3 rows, the disclosure does not limit the amount of the electronic elements and the arrangement of the electronic elements in the electronic device.

To sum up, in the electronic device in the embodiments of the disclosure, the first conductive element is disposed on the first power line, at least a portion of the first conductive element is disposed in the first opening of the insulating layer, and the first conductive element is enabled to be electrically connected to the first power line. In this way, by increasing the first conductive element, the conductive area for transmitting power signal may be increased, thereby reducing the resistivity of wires, improving the problem of IR drop, or uniforming the electric property of the electronic element in the electronic device.

Finally, it should be noted that the foregoing embodiments are only used to illustrate the technical solutions of the disclosure, but not to limit the disclosure; although the disclosure has been described in detail with reference to the foregoing embodiments, persons of ordinary skill in the art should understand that the technical solutions described in the foregoing embodiments can still be modified, or parts or all of the technical features thereof can be equivalently replaced; however, these modifications or substitutions do not deviate the essence of the corresponding technical solutions from the scope of the technical solutions of the embodiments of the disclosure.

What is claimed is:

1. An electronic device, comprising:
a substrate;
a first conductive layer, disposed on the substrate and comprising a first power line;
an insulating layer, disposed on the first conductive layer and having a first opening, wherein the first opening exposes the first power line;
a second conductive layer, disposed on the insulating layer and comprising a first conductive element, wherein at least a portion of the first conductive element is disposed in the first opening and electrically connected to the first power line; and
an electronic element, disposed on the insulating layer and electrically connected to the first power line.

2. The electronic device according to claim 1, wherein the first conductive element comprises nickel.

3. The electronic device according to claim 1, wherein in a thickness direction of the substrate, the first power line and the electronic element are disposed in a staggered manner.

4. The electronic device according to claim 1, wherein the insulating layer has a second opening, and the first conductive layer further comprises a second power line, wherein the second opening exposes the second power line;
wherein the second conductive layer further comprises a second conductive element, and at least a portion of the second conductive element is disposed in the second opening and electrically connected to the second power line.

5. The electronic device according to claim 4, wherein the second conductive element overlaps with the second power line in a normal direction of the substrate.

6. The electronic device according to claim 4, wherein the second conductive element is in contact with the second power line.

7. The electronic device according to claim 4, wherein in a thickness direction of the substrate, the second power line does not overlap with the electronic element.

8. The electronic device according to claim 4, further comprising:
a driving element, electrically connected to the first power line and the second power line, respectively,
wherein the first power line and the second power line transmit different power signals, respectively.

9. The electronic device according to claim 1, wherein the insulating layer has a third opening, and the first conductive layer further comprises a first conductive pad, wherein the third opening exposes the first conductive pad;
wherein the second conductive layer further comprises a third conductive element, and at least a portion of the third conductive element is disposed in the third opening and electrically connected to the first conductive pad.

10. The electronic device according to claim 9, wherein the third conductive element overlaps the first conductive pad in a normal direction of the substrate.

11. The electronic device according to claim 9, wherein the electronic element is bonded to the first conductive pad.

12. The electronic device according to claim 1, further comprising:
a transistor, disposed on the substrate and comprising an electrode,
wherein the first conductive layer comprises the electrode.

13. The electronic device according to claim 1, wherein the first conductive element overlaps with the first power line in a normal direction of the substrate.

14. The electronic device according to claim 1, wherein the first conductive element is in contact with the first power line.

15. The electronic device according to claim 1, wherein a width of the first conductive element is greater than a width of the first power line.

16. The electronic device according to claim 1, wherein the first power line comprises a main line and a branch, the main line extends in a first direction, the branch extends in a second direction, the first direction and the second direction are different, and at least a portion of the first conductive element extends in the first direction.

17. The electronic device according to claim 16, wherein the at least a portion of the first conductive element overlaps with the main line of the first power line in a normal direction of the substrate.

18. The electronic device according to claim 1, wherein the first power line comprises a main line and a branch, the main line extends in a first direction, the branch extends in a second direction, the first direction and the second direction are different, and at least a portion of the first conductive element extends in the second direction.

19. The electronic device according to claim 18, wherein the at least a portion of the first conductive element overlaps with the branch of the first power line in a normal direction of the substrate.

20. The electronic device according to claim 1, further comprising:
a third conductive layer, disposed on the first conductive element and covering the first conductive element.
